(19) United States
(12) Patent Application Publication
(10) Pub. No.: US 2019/0179701 A1
(43) Pub. Date: Jun. 13, 2019

(54) SEMICONDUCTOR APPARATUS

(71) Applicant: SK hynix Inc., Icheon-si Gyeonggi-do (KR)

(72) Inventor: Gang Sik LEE, Anyang-si Gyeonggi-do (KR)

(73) Assignee: SK hynix Inc., Icheon-si Gyeonggi-do (KR)

(21) Appl. No.: 16/027,769

(22) Filed: Jul. 5, 2018

(30) Foreign Application Priority Data
Dec. 8, 2017 (KR) 10-2017-0168159

(51) Int. Cl. G06F 11/10; G11C 17/16; G11C 29/52

(52) U.S. Cl. CPC G06F 11/1068; G11C 29/52; G11C 17/16

(57) ABSTRACT

A semiconductor apparatus may include a fuse circuit, registers, and an error correction circuit. The fuse circuit may be configured to generate a first fuse array signal and a second fuse array signal based on external repair information. The registers may be configured to store the first and second fuse array signals, and output stored signals as first fuse information and second fuse information. The error correction circuit may be configured to generate error correction information based on the first fuse information and the second fuse information.

### CROSS-REFERENCES TO RELATED APPLICATION

The present application claims priority under 35 U.S.C. § 119(a) to Korean application number 10-2017-0168159, filed on Dec. 8, 2017, in the Korean Intellectual Property Office, which is incorporated herein by reference in its entirety.

### BACKGROUND

### 1. Technical Field

Various embodiments generally relate to a semiconductor integrated circuit, and, more particularly, to a semiconductor apparatus.

### 2. Related Art

A semiconductor apparatus is configured to receive an electrical signal, store the received signal, and output the stored signal.

The semiconductor apparatus includes normal memory cells and redundancy memory cells to store an electrical signal. In the case where a failure occurs in a normal memory cell, a repair operation of replacing the normal memory cell in which the failure has occurred, with a redundancy memory cell, is performed.

### SUMMARY

In accordance with an embodiment, a semiconductor apparatus may include a fuse circuit, registers, and an error correction circuit. The fuse circuit may be configured to generate a first fuse array signal and a second fuse array signal based on external repair information. The registers may be configured to store the first and second fuse array signals, and output stored signals as first fuse information and second fuse information. The error correction circuit may be configured to generate error correction information based on the first fuse information and the second fuse information.

In accordance with an embodiment, a semiconductor apparatus may include a fuse circuit, a first error correction circuit, a register, and a second error correction circuit. The fuse circuit may be configured to generate a fuse array signal based on external repair information. The first error correction circuit may be configured to correct an error of the fuse array signal, and output first error correction information. The register may be configured to store the first error correction information, and output a stored signal as fuse information. The second error correction circuit may be configured to correct an error of the fuse information, and output second error correction information.

### BRIEF DESCRIPTION OF THE DRAWINGS

FIG. 1 is a configuration diagram illustrating an example of a semiconductor apparatus in accordance with an embodiment.

FIG. 2 is a configuration diagram illustrating an example of the fuse circuit of FIG. 1 in accordance with an embodiment.

FIG. 3 is a configuration diagram illustrating an example of the fuse circuit of FIG. 1 in accordance with an embodiment.

FIG. 4 is a configuration diagram illustrating an example of a semiconductor apparatus in accordance with another embodiment.

### DETAILED DESCRIPTION

Hereinafter, a semiconductor apparatus will be described below with reference to the accompanying drawings through various examples of embodiments.

Various embodiments are directed to a semiconductor apparatus that may be capable of performing an accurate repair operation.

Since a semiconductor apparatus may perform an accurate repair operation, the reliability of the semiconductor apparatus may be improved.

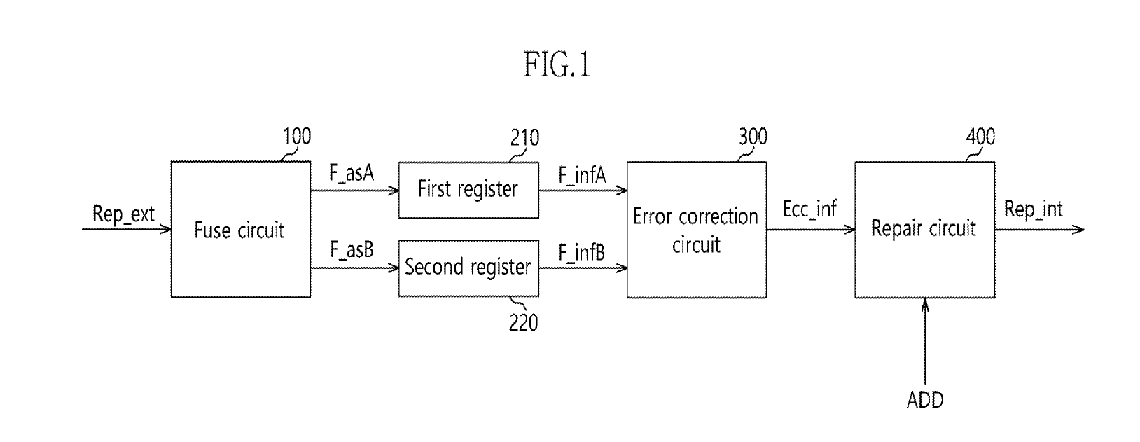

As illustrated in FIG. 1, a semiconductor apparatus in accordance with an embodiment may include a fuse circuit 100, first and second registers 210 and 220, an error correction circuit 300, and a repair circuit 400.

The fuse circuit 100 may generate and output a first fuse array signal F_asA and a second fuse array signal F_asB in response to an external repair information Rep_ext. For example, the fuse circuit 100 may perform a fuse rupture operation in response to the external repair information Rep_ext, and may output the signals of ruptured fuses as the first fuse array signal F_asA and the second fuse array signal F_asB. The first fuse array signal F_asA may include the external repair information Rep_ext, and the second fuse array signal F_asB may include a result of a specific calculation operation for the external repair information Rep_ext. The specific calculation operation may include a parity calculation operation.

The first register 210 may store the first fuse array signal F_asA, and output the stored signal as first fuse information F_infA,

The second register 220 may store the second fuse array signal F_asB, and output the stored signal as second fuse information F_infB.

The error correction circuit 300 may generate and output error correction information Ecc_inf in response to the first fuse information F_infA and the second fuse information F_infB. For is example, the error correction circuit 300 may perform an error correction operation in response to the first fuse information F_infA and the second fuse information F_infB, and may generate and output the error correction information Ecc_inf as a result of the error correction operation. The error correction circuit 300 may include an error correction code (ECC) circuit. While the error correction circuit 300 is described, for example, as a circuit which performs an error correction operation by using an ECC code or parity bits, any error correction circuit which performs an error correction operation by using the scheme of a specific code such as a Hamming code, a Huffman code, a turbo code, a cyclic code, a Reed-Muller code, and a Reed-Solomon error correction code may be applied. A parity operation that is performed in the fuse circuit 100 may be changed to an operation of generating a different code, depending on a code scheme used in the error correction circuit 300.

The repair circuit 400 may generate and output an internal repair information Rep_int in response to the error correction information Ecc_inf and an address ADD. For example, the repair circuit 400 may compare the error correction information Ecc_inf with the address ADD, and may generate and output the internal repair to information Rep_int when the error correction information Ecc_inf corresponds to the address ADD.

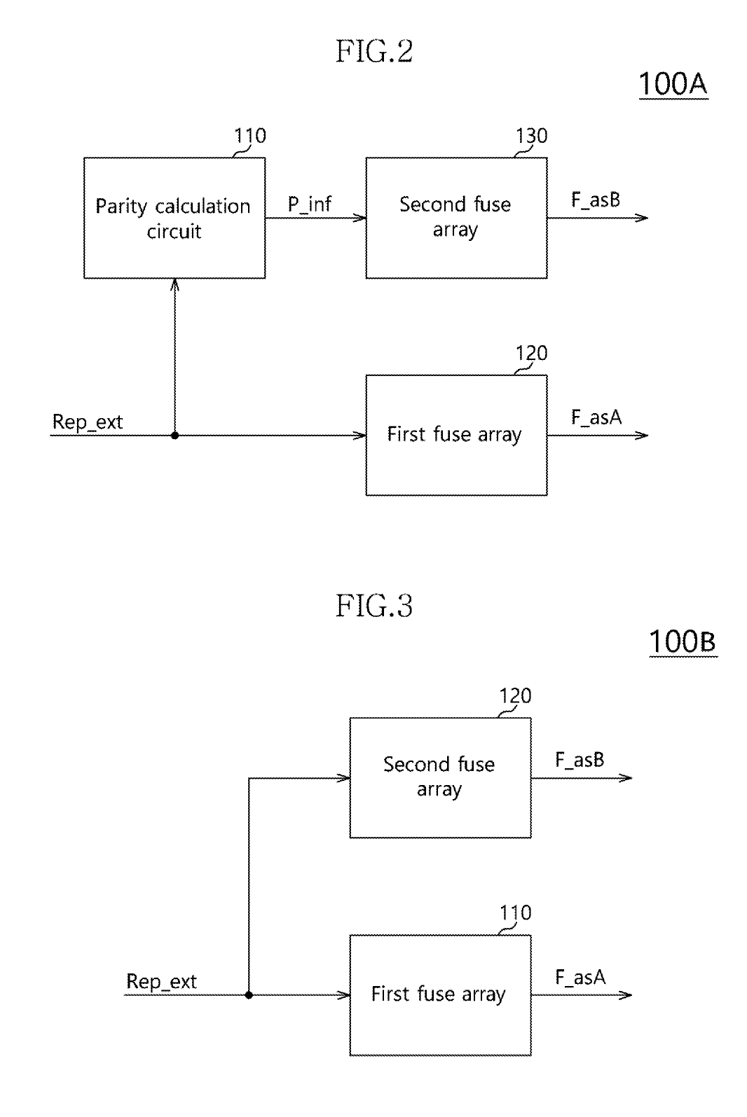

As illustrated in FIG. 2, the fuse circuit 100A may include a parity calculation circuit 110, a first fuse array 120, and a second fuse array 130.

The parity calculation circuit 110 may perform a parity calculation in response to the external repair information Rep_ext, and may output a result of performing the parity calculation as a parity information P_inf.

The first fuse array 120 may include a plurality of fuses.

The first fuse array 120 may rupture the plurality of fuses in response to the external repair information Rep_ext, and may output the signals of ruptured fuses as the first fuse array signal F_asA.

The second fuse array 130 may include a plurality of fuses.

The second fuse array 130 may rupture the plurality of fuses in response to the parity information P_inf, and may output the signals of ruptured fuses as the second fuse array signal F_asB. The fuses which are included in each of the first and second fuse arrays 120 and 130 may be resistive fuse elements. The resistive fuse elements may have high resistance in a state in which they are not ruptured (programmed) and may have low resistance after a state in which they are ruptured (programmed). The resistive fuse elements may have the structure of an electrode/an insulator/an electrode, and the insulator may be a silicon dioxide, a silicon nitride, a tantalum oxide, an ONO (silicon dioxide-silicon nitride-silicon dioxide), etc. A to fuse rupture operation may include an operation of applying a high voltage to an electrode for a sufficient time and thereby destroying an insulator which forms a fuse.

The fuse circuit 100A configured as illustrated in FIG. 2 includes the parity calculation circuit 110, and thereby, may generate the parity information P_inf according to the external repair information Rep_ext and output the parity information P_inf as the second fuse array signal F_asB.

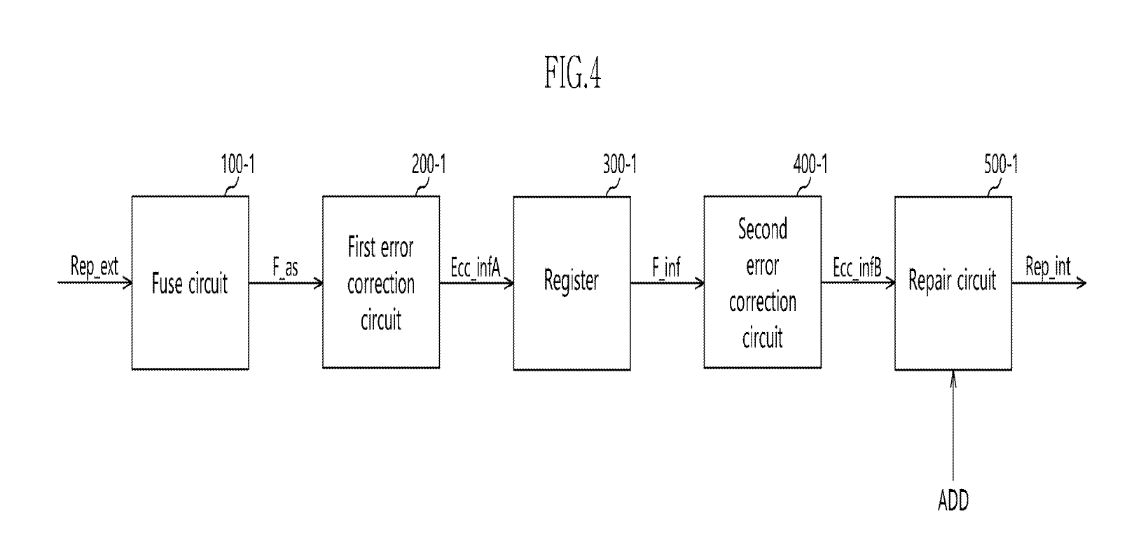

The fuse circuit 100B illustrated in FIG. 3 represents a configuration in the case where the parity information P_inf is included in the external repair information Rep_ext.

A first fuse array 110 may perform a fuse rupture operation in response to information which is included in the external repair information Rep_ext except the parity information P_inf, and may output the signals of ruptured fuses as a first fuse array signal F_asA.

A second fuse array 120 may perform a fuse rupture operation in response to the parity information P_inf included in the external repair information Rep_ext, and may output the signals of ruptured fuses as a second fuse array signal F_asB.

In the fuse circuit 100B configured as illustrated in FIG. 3, the fuse circuit 100B might not include a parity calculation circuit since the parity information P_inf is included in the external repair information Rep_ext.

The operation of the semiconductor apparatus in accordance with embodiments of the present disclosure, configured as mentioned to above, will be described below. The fuse circuit 100 may generate and output the first and second fuse array signals F_asA and F_asB in response to the external repair information Rep_ext. The fuse circuit 100 may output the external repair information Rep_ext as the first fuse array signal F_asA, and may output a parity calculation result of is the external repair information Rep_ext as the second fuse array signal F_asB,

If a parity calculation result is not included in the external repair information Rep_ext, the fuse circuit 100 (see FIG. 1) may include the parity calculation circuit 110 as illustrated in FIG. 2. If a parity calculation result is included in the external repair information Rep_ext, the fuse circuit 100 (see FIG. 1) might not include a parity calculation circuit as illustrated in FIG. 3.

The operation of the fuse circuit 100 will be described with reference to FIG. 2. The fuse circuit 100A may store the external repair information Rep_ext inputted from an external equipment or an external circuit, in the first fuse array 120. The first fuse array 120 may perform a rupture operation for fuses in response to the external repair information Rep_ext, and may output information on ruptured fuses, as the first fuse array signal F_asA.

The parity calculation circuit 110 may calculate the parity of the external repair information Rep_ext, and may output a parity calculation result as the parity information P_inf.

The second fuse array 130 may store the parity information P_inf. The second fuse array 130 may perform a rupture operation to for fuses in response to the parity information P_inf, and may output information on ruptured fuses, as the second fuse array signal F_asB.

The first and second fuse array signals F_asA and F_asB outputted from the fuse circuit 100A may be inputted to the first and second registers 210 and 220, respectively.

The first register 210 may store the first fuse array signal F_asA, and output the stored information as the first fuse information F_infA.

The second register 220 may store the second fuse array signal F_asB, and output the stored information as the second fuse information F_infB. The first and second registers 210 and 220 may receive and store the first and second fuse array signals F_asA and F_asB from the first and second fuse arrays 120 and 130 in a boot-up operation of the semiconductor apparatus, and may output the stored signals as the first fuse information F_infA and the second fuse information F_infB.

The error correction circuit 300 may generate the error correction information Ecc_inf in response to the first fuse information F_infA and the second fuse information F_infB. For example, when assuming that the external repair information Rep_ext is included in the first fuse information F_infA and a parity calculation result of the external repair information Rep_ext is included in the second fuse information F_infB, the error correction circuit 300 may correct an error of the first fuse information F infA based on the second fuse information F_infB, and may output the corrected information as the to error correction information Ecc_inf.

The repair circuit 400 may generate and output the internal repair information Rep_int in response to the error correction information Ecc_inf and the address ADD. For example, the repair circuit 400 may compare the error correction information Ecc_inf with is the address ADD, and may generate and output the internal repair information Rep_int according to preset information when the error correction information Ecc_inf corresponds to the address ADD.

In the semiconductor apparatus in accordance with embodiments of the present disclosure, in order to improve the reliability of a repair operation, an error correction operation for repair information inputted from an exterior (i.e., external repair information input from outside) is performed, and a repair operation is performed by comparing the repair information for which the error correction operation is performed with an address. In particular, as illustrated in FIG. 1, by disposing the error correction circuit 300 at a stage immediately before the repair circuit 400, the errors of a signal which is inputted to the repair circuit 400 may be eliminated, and thus, the reliability of a repair operation may be improved.

FIG. 4 illustrates a semiconductor apparatus in accordance with another embodiment of the present disclosure. The semiconductor apparatus may include a fuse circuit 100-1, a first error correction circuit 200-1, a register 300-1, a second error correction circuit 400-1 and a repair circuit 500-1.

The fuse circuit 100-1 may include a plurality of fuses, to perform a rupture operation for the plurality of fuses in response to external repair information Rep_ext, and output a result of the rupture operation as a fuse array signal F_as. The fuse circuit 100-1 may be configured in the same manner as the fuse circuit 100A illustrated in FIG. 2 or the fuse circuit 100B in FIG. 3. Therefore, both parity information and repair information may be included in the fuse array signal F_as.

The first error correction circuit 200-1 may perform an error correction operation for the fuse array signal F_as, and may output the error-corrected signal as first error correction information Ecc_infA. The first error correction circuit 200-1 may include an ECC circuit.

The register 300-1 may store the first error correction information Ecc_infA, and output the stored information as fuse information F_inf. The register 300-1 may include first and second registers 210 and 220 illustrated in FIG. 1. In an embodiment, the register 300-1 may receive and store the first error correction information Ecc infA from the first error correction circuit 200-1 in a boot-up operation of the semiconductor apparatus, and may output the stored information as the fuse information F_inf.

The second error correction circuit 400-1 may perform an error correction operation for the fuse information F_inf, and may output the error-corrected information as second error correction information Ecc_infB. The second error correction circuit 400-1 may include an ECC circuit.

The repair circuit 500-1 may compare the second error correction information Ecc_infB with an address ADD, and output internal repair information Rep_int.

In the semiconductor apparatus illustrated in FIG. 4 in accordance with embodiments of the present disclosure, by disposing an error correction circuit between a fuse circuit and a register, an error likely to occur in the fuse circuit may be corrected. Also, by disposing an error correction circuit between the register and a repair circuit, an error likely to occur in the register may be corrected, and then, a repair operation may be performed.

In the semiconductor apparatus illustrated in FIG. 4 in accordance with embodiments of the present disclosure, when compared to the semiconductor apparatus illustrated in FIG. 1, by additionally disposing the error correction circuit between the fuse circuit and the register, error correction capability may be improved.

While various embodiments have been described above, it will be understood to those skilled in the art that the embodiments described are examples only. Accordingly, the semiconductor apparatus described herein should not be limited based on the described embodiments.

What is claimed is:

1. A semiconductor apparatus comprising:
a fuse circuit configured to generate a first fuse array signal and a second fuse array signal based on external repair information;
registers configured to store the first and second fuse array signals, and output stored signals as first fuse information and second fuse information;
an error correction circuit configured to generate error correction information based on the first fuse information and the second fuse information; and
a repair circuit configured to generate internal repair information based on an address and the error correction information.

2. The semiconductor apparatus according to claim 1,
wherein the fuse circuit outputs the first fuse array signal including the external repair information, and
wherein the fuse circuit outputs the second fuse array signal including parity information of the external repair information.

3. The semiconductor apparatus according to claim 1, wherein the fuse circuit comprises:
a parity calculation circuit configured to calculate a parity of the external repair information, and generate parity information;
a first fuse array configured to perform a fuse rupture operation based on the external repair information, and generate the first fuse array signal as a result of the fuse rupture operation based on the external repair information; and
a second fuse array configured to perform a fuse rupture operation based on the parity information, and generate the second fuse array signal as a result of the fuse rupture operation based on the parity information.

4. The semiconductor apparatus according to claim 3, wherein each of the first and second fuse arrays includes a plurality of resistive fuse elements.

5. The semiconductor apparatus according to claim wherein first and second registers of the registers store and output the first and second fuse array signals in a boot-up operation of the semiconductor apparatus.

6. The semiconductor apparatus according to claim 1, wherein the fuse circuit comprises:
a first fuse array configured to perform a fuse rupture operation based on the external repair information except parity information included in the external repair information, and generate the first fuse array signal as a result of the fuse rupture operation based on the external repair information except the parity information included in the external repair information; and
a second fuse array configured to perform a fuse rupture operation based on the parity information included in the external repair information, and generate the second fuse array signal as a result of the fuse rupture operation based on the parity information included in the external repair information.

7. The semiconductor apparatus according to claim wherein the error correction circuit performs an error correction operation for the first fuse information based on the second fuse information, and generates the error correction information as a result of the error correction operation.

8. The semiconductor apparatus according to claim 7, wherein the repair circuit compares the error correction information with the address, and generates and outputs the internal repair information according to preset information when the error correction information corresponds to the address.

9. A semiconductor apparatus comprising:
a fuse circuit configured to generate a fuse array signal based on external repair information;
a first error correction circuit configured to correct an error of the fuse array signal, and output first error correction information;
a register configured to store the first error correction information, and output a stored signal as fuse information;
a second error correction circuit configured to correct an error of the fuse information, and output second error correction information; and
a repair circuit configured to output internal repair information based on the second error correction information and an address.

10. The semiconductor apparatus according to claim 9,
wherein the fuse circuit includes a plurality of fuses, and
wherein the fuse circuit performs a rupture operation for the plurality of fuses based on the external repair information, and outputs a result of the rupture operation as the fuse array signal.

11. The semiconductor apparatus according to claim 10, wherein the plurality of fuses include resistive fuse elements.

12. The semiconductor apparatus according to claim 9, wherein the register stores the first error correction information in a boot-up operation of the semiconductor apparatus, and outputs a stored signal as the fuse information.

13. The semiconductor apparatus according to claim 9, wherein each of the first and second error correction circuits comprises an error correction code (ECC) circuit.

14. The semiconductor apparatus according to claim 13, wherein the repair circuit compares the second error correction information with the address, and generates and outputs the internal repair information according to preset information when the second error correction information corresponds to the address.
